(19) United States
(12) Patent Application Publication
(10) Pub. No.: US 2026/0214938 A1
(43) Pub. Date: Jul. 23, 2026

(54) SEMICONDUCTOR DEVICE

(71) Applicant: Fuji Electric Co., Ltd., Kawassaki-shi (JP)

(72) Inventor: Katsunori UENO, Matsumoto-city (JP)

(73) Assignee: Fuji Electric Co., Ltd., Kawassaki-shi (JP)

(21) Appl. No.: 19/569,695

(22) Filed: Mar. 17, 2026

Related U.S. Application Data
(63) Continuation of application No. PCT/JP2025/012860, filed on Mar. 28, 2025.

(30) Foreign Application Priority Data
Apr. 5, 2024 (JP) 2024-061645

(51) Int. Cl. H10D 30/66; H10D 62/17; H10D 64/27

(52) U.S. Cl. CPC H10D 30/668; H10D 62/393; H10D 64/519

(57) ABSTRACT

A semiconductor device reduces on-resistance. The device includes a gate electrode, a first conductivity-type contact region, and super-junction drift layers. The drift layers form a first stripe pattern in which first- and second-conductivity-type column layers extending in a first direction are alternately arranged in a second direction. The gate electrode forms a second stripe pattern in which trench gates extending in the second direction are arranged in the first direction, and the two stripe patterns intersect in plan view. When the repetition period of the column layers is a first period and the repetition period of the trench gates is a second period, the second period is shorter than the first period. The contact region has a higher first-conductivity-type concentration and a larger second-direction width than the first column layer.

### CROSS-REFERENCE TO RELATED APPLICATION

This application is a Continuation of PCT Application No. PCT/JP 2025/012860, filed on Mar. 28, 2025, and claims the priority of Japanese Patent Application No. 2024-061645, filed on Apr. 5, 2024, the content of which are incorporated herein by reference.

### BACKGROUND OF THE INVENTION

### 1. Field of the Invention

The present disclosure relates to a semiconductor device.

### 2. Description of the Related Art

A superjunction semiconductor element is known which has a parallel pn junction layer configured by alternately and repeatedly joining a plurality of drift layers containing a first conductivity-type semiconductor extending from a first principal surface toward a second principal surface of a semiconductor substrate and a plurality of partition regions containing a second conductivity-type semiconductor extending in the same manner as the drift layers in a direction intersecting the extension directions thereof and in which the parallel pn junction layer passes current when the parallel pn junction layer is in the on state and is depleted when the parallel pn junction layer is in the off state (see JP 2002-76339 A, for example).

### SUMMARY OF THE INVENTION

In a semiconductor device having a super junction (hereinafter also referred to as SJ) structure, a further reduction in on-resistance has been demanded.

The present disclosure has been made in view of the above-described problem, and aims to provide a semiconductor device capable of further reducing on-resistance.

### Solution to Problem

To solve the above-described problem, a semiconductor device according to one aspect of the present disclosure includes: a semiconductor layer; a gate electrode provided on a first surface of the semiconductor layer; a first conductivity-type contact region provided in the semiconductor layer; and drift layers of a super junction structure provided in the semiconductor layer. The drift layers contain a plurality of first conductivity-type first column layers extended in a first direction and a plurality of second conductivity-type second column layers extended in the first direction and have a first stripe pattern where the first column layers and the second column layers are alternately aligned in a second direction intersecting the first direction. The gate electrode contains a plurality of trench gates extended in the second direction and has a second stripe pattern where the plurality of trench gates is aligned in the first direction. The first stripe pattern and the second stripe pattern intersect each other in plan view. When the repetition period of the first column layers or the second column layers in the second direction of the first stripe pattern is set as a first period and the repetition period of the trench gates in the first direction of the second stripe pattern is set as a second period, the second period is shorter than the first period. The contact region has a concentration of the first conductivity type higher than that of the first column layer and a width in the second direction larger than that of the first column layer.

A semiconductor device according to another aspect of the present disclosure includes: a semiconductor layer; a gate electrode provided on a first surface of the semiconductor layer; a first conductivity-type contact region provided in the semiconductor layer; and drift layers of a super junction structure provided in the semiconductor layer. The drift layers contain a plurality of first conductivity-type first column layers extended in a first direction and a plurality of second conductivity-type second column layers extended in the first direction and have a first stripe pattern where the first column layers and the second column layers are alternately aligned in a second direction intersecting the first direction. The gate electrode contains a plurality of trench gates extended in the second direction and has a second stripe pattern where the plurality of trench gates is aligned in the first direction. The first stripe pattern and the second stripe pattern intersect each other in plan view. When the repetition period of the first column layers or the second column layers in the second direction of the first stripe pattern is set as a first period and the repetition period of the trench gates in the first direction of the second stripe pattern is set as a second period, the second period is shorter than the first period. The contact region has a concentration of the first conductivity type higher than that of the first column layer. The drift layers further have a third column layer provided in the semiconductor layer and positioned under the contact region. The conductivity type of the third column layer is a first conductivity type having a concentration lower than that of the first column layer or a second conductivity type having a concentration lower than that of the second column layer. The third column layer is extended in the first direction and has a width in the second direction larger than that of the first column layer.

### BRIEF DESCRIPTION OF THE DRAWINGS

FIG. 1 is a plan view illustrating a configuration example of an insulated gate semiconductor device according to an embodiment 1 of the present disclosure;

FIG. 2 is a plan view illustrating a configuration example of the insulated gate semiconductor device according to the embodiment 1 of the present disclosure;

FIG. 3 is a plan view illustrating a configuration example of the insulated gate semiconductor device according to the embodiment 1 of the present disclosure;

FIG. 4 is a cross-sectional view illustrating a configuration example of the insulated gate semiconductor device according to the embodiment 1 of the present disclosure;

FIG. 5 is a cross-sectional view illustrating a configuration example of the insulated gate semiconductor device according to the embodiment 1 of the present disclosure;

FIG. 6 is a cross-sectional view illustrating a configuration example of the insulated gate semiconductor device according to the embodiment 1 of the present disclosure;

FIG. 7 is a cross-sectional view illustrating a configuration example of the insulated gate semiconductor device according to the embodiment 1 of the present disclosure;

FIG. 8 is a perspective view illustrating a configuration example of the insulated gate semiconductor device according to the embodiment 1 of the present disclosure;

FIG. 9 is a cross-sectional view illustrating a configuration example of an insulated gate semiconductor device according to a modification of the embodiment 1 of the present disclosure;

FIG. 10 is a cross-sectional view illustrating a configuration example of the insulated gate semiconductor device according to the modification of the embodiment 1 of the present disclosure;

FIG. 11 is a plan view illustrating a configuration example of an insulated gate semiconductor device according to an embodiment 2 of the present disclosure;

FIG. 12 is a cross-sectional view illustrating a configuration example of the insulated gate semiconductor device according to the embodiment 2 of the present disclosure;

FIG. 13 is a cross-sectional view illustrating a configuration example of the insulated gate semiconductor device according to the embodiment 2 of the present disclosure;

FIG. 14 is a graph showing the results of an experiment performed by the present disclosers and the relation between a trench pitch and an on-resistance RonA; and

FIG. 15 is a graph created based on the graph in FIG. 14 and is a graph showing the relation between the trench pitch and a reduction rate from non-SJ of the RonA.

### DETAILED DESCRIPTION

Hereinafter, embodiments of the present disclosure are described. In the description of the drawings below, the same or similar reference signs are attached to the same or similar portions. It should be noted that the drawings are schematic, and the relation between the thickness and the plane dimension, the thickness ratio of each device or each member, and the like are different from the actual relation, thickness ratio, and the like. Therefore, the specific thickness and dimension should be determined in consideration of the description below.

It is a matter of course that the drawings also include portions different in mutual dimensional relations and ratios.

In the description below, the positive direction of the Z-axis is sometimes referred to as “upper” and the negative direction of the Z-axis is sometimes referred to as “lower”. However, the “upper” and the “lower” do not always mean the vertical direction relative to the ground. More specifically, the directions of “upper” and “lower” are not limited to the direction of gravity. “Upper” and “lower” are merely convenient expressions for specifying the relative positional relations of regions, layers, films, substrates, and the like, and do not limit the technical idea of the present disclosure. For example, it is a matter of course that, when the paper is rotated 180 degrees, “upper” becomes “lower” and “lower” become “upper”.

In the description below, the directions are sometimes described using words of an X-axis direction, a Y-axis direction, and a Z-axis direction. For example, the X-axis direction and the Y-axis direction are directions parallel to a front surface 10a of a GaN layer 10 described later. The Z-axis direction is the normal direction of the front surface 10a of the GaN layer 10 and is also the thickness direction of the GaN layer 10. The X-axis direction, the Y-axis direction, and the Z-axis direction are orthogonal to each other.

In the description below, plan view means viewed from the normal direction (e.g., Z-axis direction) of the front surface 10a of the GaN layer 10.

In the description below, a case where a first conductivity type is a P-type and a second conductivity type is an N-type is illustratively described. However, it may be acceptable to select the conductivity type in an inverse relation, with the first conductivity type as the N-type and the second conductivity type as the P-type. +and-attached to P and N mean that semiconductor regions attached by + and − have a relatively higher or lower impurity concentration than that of semiconductor regions not attached by + and −, respectively.

However, even when semiconductor regions are attached by the same P and P (or N and N), it does not mean that the impurity concentrations of the semiconductor regions are exactly the same.

### Embodiment 1

### Configuration Example of Insulated Gate Semiconductor Device

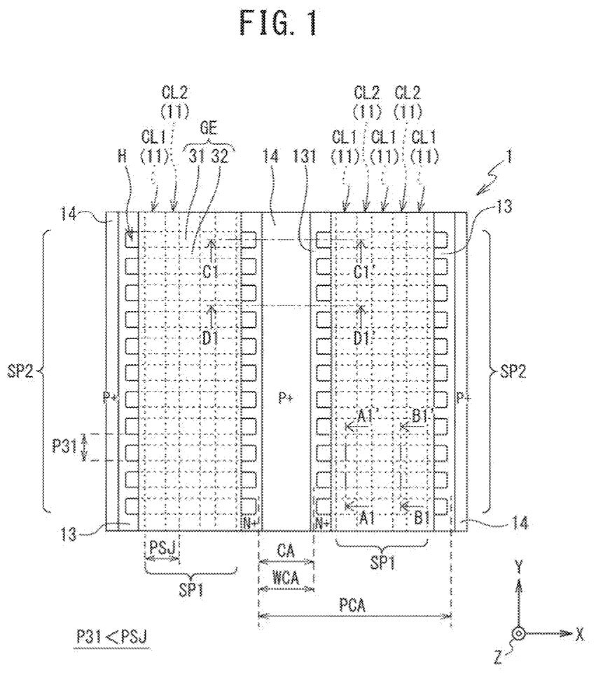

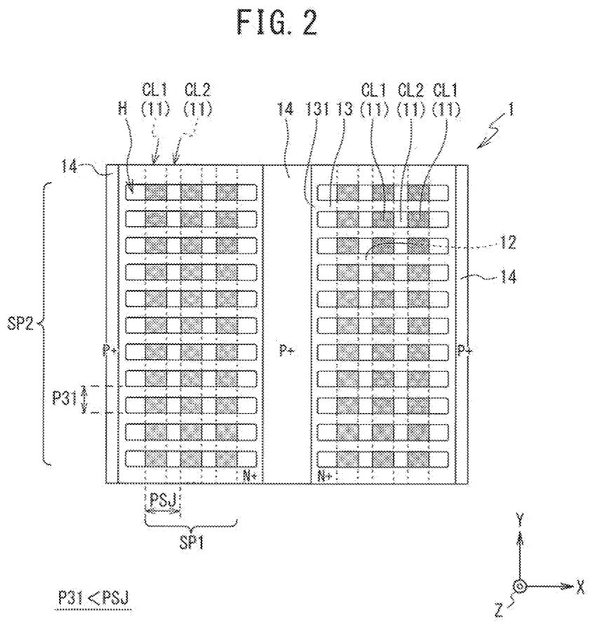

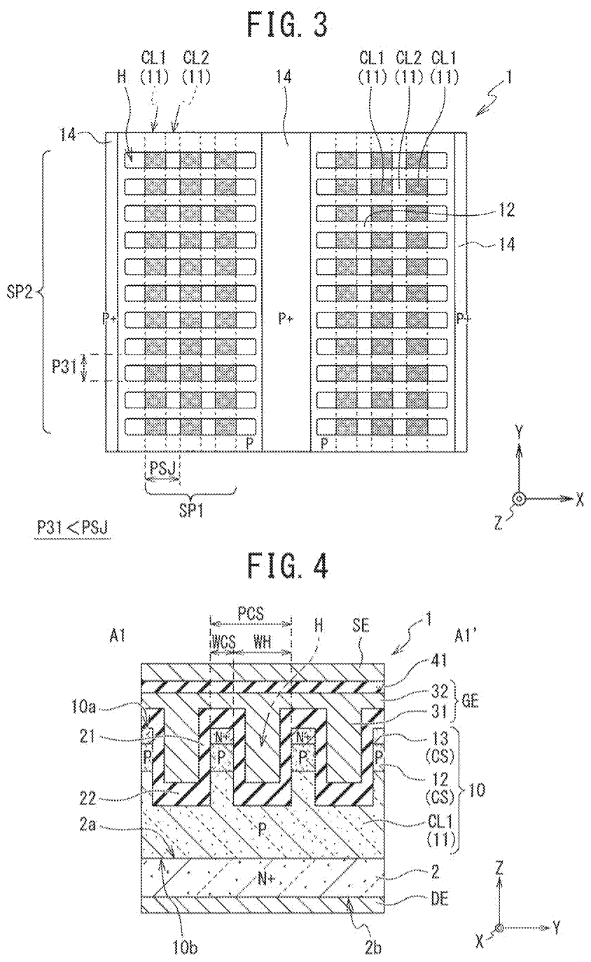

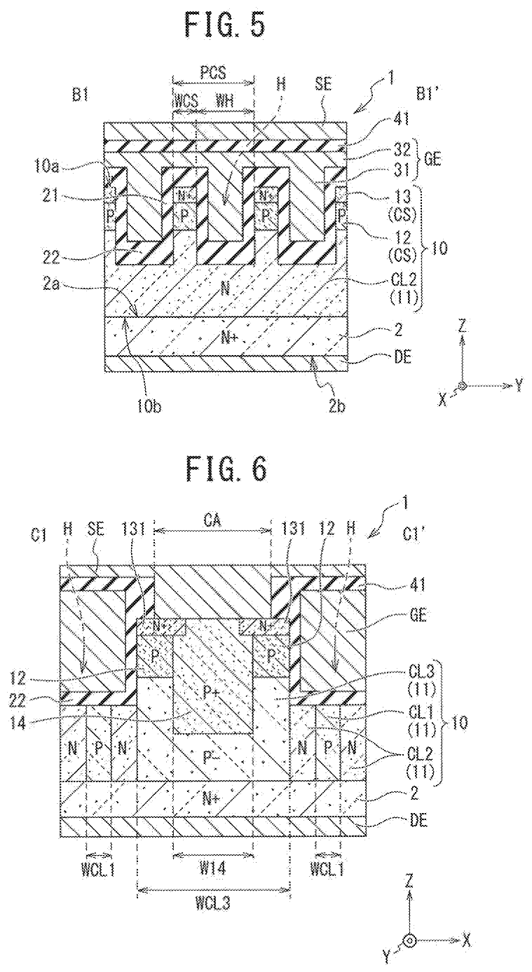

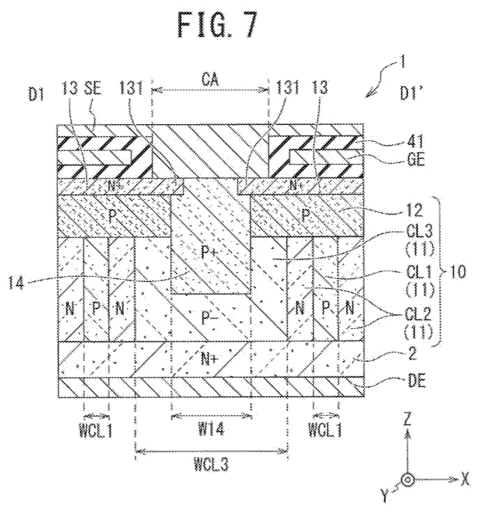

FIGS. 1 to 3 are plan views illustrating configuration examples of an insulated gate semiconductor device 1 (one example of the “semiconductor device” of the present disclosure) according to an embodiment 1 of the present disclosure. FIG. 2 is a view in which a gate electrode GE is removed from the plan view illustrated in FIG. 1. FIG. 3 is a view in which source regions 13 and source drawing regions 131 are removed from the plan view illustrated in FIG. 2. FIGS. 4 to 7 are cross-sectional view illustrating configuration examples of the insulated gate semiconductor device 1 according to the embodiment 1 of the present disclosure. FIG. 4 illustrates the cross-section in which the plan view illustrated in FIG. 1 is cut along the A1-A1′ line. FIG. 5 illustrates the cross-section in which the plan view illustrated in FIG. 1 is cut along the B1-B1′ line. FIG. 6 illustrates the cross-section in which the plan view illustrated in FIG. 1 is cut along the C1-C1′ line. FIG. 7 illustrates the cross-section in which the plan view illustrated in FIG. 1 is cut along the D1-D1′ line.

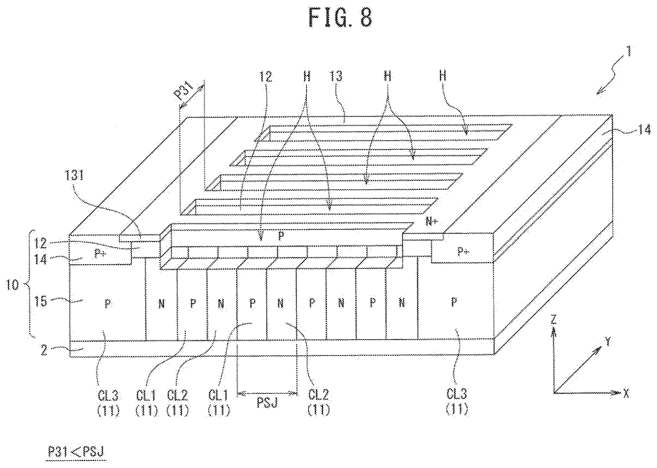

FIG. 8 is a perspective view illustrating a configuration example of the insulated gate semiconductor device 1 according to the embodiment 1 of the present disclosure. FIG. 8 does not illustrate a gate insulating film 21, the gate electrode GE, an insulating film 41, and a source electrode SE to intelligibly illustrate the configurations of P-type first column layers CL1, N-type second column layers CL2, well regions 12, the source regions 13, and the source drawing regions 131 illustrated in FIGS. 1 to 7.

FIGS. 1 to 3 illustrate, as an example, a case where the number of the first column layers CL1 present in a region sandwiched by P⁺-type contact regions 14 in plan view (hereinafter also referred to as an active region) is three. FIG. 8 illustrates, as an example, a case where the number of the first column layers CL1 present in one active region is four.

As illustrated in FIGS. 1 to 8, the insulated gate semiconductor device 1 is a vertical MOSFET (Metal Oxide Semiconductor Field Effect Transistor) having a trench gate structure. For example, the insulated gate semiconductor device 1 includes an N⁺-type gallium nitride substrate (hereinafter, GaN substrate) 2 and an N-type gallium nitride layer 10 (hereinafter, GaN layer 10; one example of the “semiconductor layer” of the present disclosure) provided on a front surface 2a of the GaN substrate 2. The GaN layer 10 includes drift layers 11 of a super junction structure (i.e., SJ structure), P-type well regions 12, the source regions 13 of N⁺-type conductivity, the drawing regions 131 of N⁺-type conductivity, and the P⁺-type contact regions 14.

The insulated gate semiconductor device 1 also includes a plurality of trenches H provided in the GaN layer 10, a gate insulating film 21 provided in the trenches H, the gate electrode GE provided on the front surface 10a (one example of the “first surface” of the present disclosure) of the GaN layer 10, the source electrode SE provided on the front surface 10a of the GaN layer 10, and an insulating film 41 provided on the front surface 10a of the GaN layer 10 and positioned between the gate electrode GE and the source electrode SE. The insulated gate semiconductor device 1 also includes a drain electrode DE provided on a rear surface 2b of the GaN substrate 2. Hereinafter, each part constituting the insulated gate semiconductor device 1 is described in detail.

The GaN substrate 2 is a GaN single crystal substrate. The GaN substrate 2 is an N-type substrate and is, for example, an N⁺-type substrate. An N-type impurity contained in the GaN substrate 2 is one or more elements of Si (silicon), O (oxygen), and Ge (germanium). As one example, the N-type impurity contained in the GaN substrate 2 is Si or O, and the impurity concentration of Si or O in the GaN substrate 2 is 2×10¹⁸ cm⁻³ or more.

The GaN substrate 2 may be a low-dislocation freestanding substrate having a dislocation density of less than 1×10⁷ cm⁻². Due to the fact that the GaN substrate 2 is a low-dislocation freestanding substrate, the dislocation density of the GaN layer 10 formed on the GaN substrate 2 is also low. The use of the low-dislocation freestanding substrate for the GaN substrate 2 allows a reduction in leakage current in a large-area power device, even when the power device is formed on the GaN substrate 2. This allows a manufacturing device to manufacture the power device with a high non-defective rate. Further, ion-implanted impurities can be prevented from deeply diffusing along the dislocation in heat treatment.

The GaN layer 10 is provided on the front surface 2a of the GaN substrate 2. The GaN layer 10 is a GaN single crystal layer and is a layer epitaxially formed on the front surface 2a of the GaN substrate 2. The GaN layer 10 is formed by doping with an N-type impurity in the epitaxial growth process.

The drift layers 11 of the SJ structure contain two or more of the P-type first column layers CL1 extended in the Y-axis direction and two or more of the N-type second column layers CL2 extended in the Y-axis direction. The drift layers 11 have a first stripe pattern SP1 (e.g., stripe pattern in the vertical direction in FIG. 1) in which the first column layers CL1 and the second column layer CL2 are alternately aligned in the X-axis direction.

The first column layer CL1 has the same or nearly the same P-type impurity concentration as that of the well region 12. The second column layer CL2 has an N-type impurity concentration lower than that of the source region 13. The first column layers CL1 and the second column layers CL2 are positioned under the well region 12 and are individually contact with the well region 12. The second column layers CL2 serve as current paths between the GaN substrate 2 and the well region 12.

As illustrated in FIGS. 6 to 8, the drift layers 11 of the SJ structure also have a P⁻-type third column layer CL3 provided in the gallium nitride layer 10 and positioned under the P⁺-type contact region 14. The third column layer CL3 is also extended in the Y-axis direction and is arranged parallel to the first stripe SP1 of the SJ structure. The third column layer CL3 has a P-type impurity concentration lower than that of the first column layer CL1. The third column layer CL3 has a width in the X-axis direction larger than that of the first column layer CL1. When the width in the X-axis direction of the first column layer CL1 is set as WCL1 and the width in the X-axis direction of the third column layer CL3 is set as WCL3, WCL1<WCL3 is established.

The well region 12 is formed by doping with a P-type impurity in the epitaxial growth process of forming the GaN layer 10. Alternatively, the well region 12 may be formed by ion implantation of a P-type impurity at a predetermined depth from the front surface 10a of the GaN layer 10, followed by heat treatment. The P-type impurity is, for example, Mg. In the well region 12, a vertical MOSFET channel is formed in a portion in contact with the gate insulating film 21 and the vicinity thereof.

In the insulated gate semiconductor device 1, the channels and the source regions 13 adjacent to the channels are repeatedly arranged at a fixed pitch in one direction (e.g., Y-axis direction). In the embodiment of the present disclosure, unit structures of the channels and the source regions 13 repeatedly arranged at a fixed pitch toward the Y-axis direction are referred to as channel cells CS.

The channel cells CS are provided in the GaN layer 10 and have the P-type well regions 12 and the N⁺-type source regions 13 in contact with the well regions 12. Two or more of the channel cells CS are individually extended in the X-axis direction. The two or more of the channel cells CS are aligned at a fixed pitch in the Y-axis direction. The Y-axis direction is a direction of the channel width of the vertical MOSFET. The channel cell CS is positioned between one of the trench gates 31 and the other one of the trench gates 31 adjacent to each other in the Y-axis direction, i.e., between one trench H and the other trench H adjacent to each other in the Y-axis direction.

The trench H is a recessed part formed by etching the GaN layer 10 from the front surface 10a side. The channel cell CS is a projection part of the semiconductor sandwiched between the trenches H and is a mesa part. The channel cell CS (i.e., mesa part) has a width WCS in the Y-axis direction of 20 nm or more and 1 μm or less, for example.

The source regions 13 and the source drawing regions 131 are provided in the front surface 10a of the GaN layer 10 and the vicinities thereof. The source regions 13 and the source drawing regions 131 are formed by ion implantation of N-type impurities at a predetermined depth from the front surface 10a of the GaN layer 10, followed by heat treatment. The source regions 13 and the source drawing regions 131 are positioned on the well regions 12 and in contact with the well regions 12.

The source region 13 is extended in the X-axis direction. The source drawing region 131 is extended in the Y-axis direction. The source region 13 has an end part in the X-axis direction connected to the source drawing region 131. The source region 13 overlaps the gate electrode GE in plan view. The source drawing region 131 does not overlap the gate electrode GE in plan view.

The P⁺-type contact region 14 is provided in the front surface 10a of the GaN layer 10 and the vicinity thereof. The contact region 14 is formed by ion implantation of a P-type impurity at a predetermined depth from the front surface 10a of the GaN layer 10, followed by heat treatment. The contact region 14 has a P-type concentration (i.e., value obtained by offsetting the N-type impurity concentration from the P-type impurity concentration) higher than that of the P-type well region 12 constituting the channel cell CS. Similarly, the contact region 14 has a P-type impurity concentration higher than that of the P-type first column layer CL1.

In the insulated gate semiconductor device 1, one group of the channel cells CS aligned in the Y-axis direction and the other group of the channel cells CS aligned in the Y-axis direction are adjacent to each other in the X-axis direction. The contact region 14 is positioned between one group of the channel cells CS and the other group of the channel cells CS adjacent to each other in the X-axis direction. The contact region 14 is extended in the Y-axis direction and arranged parallel to the first stripe SP1 of the SJ structure.

The contact region 14 is in contact with each of the well regions 12 of one group of the channel cells CS and the source drawing regions 131 and in contact with each of the well regions 12 of the other group of the channel cells CS and the source drawing regions 131. The contact region 14 has a depth from the front surface 10a side larger than the depth from the front surface 10a side of the well region 12. Thus, the contact region 14 is also in contact with the P⁻-type third column layer CL3 constituting the drift layer 11 of the SJ structure.

As illustrated in FIGS. 6 and 7, when the width in the X-axis direction of the contact region 14 is set as W14, the width W14 of the contact region 14 is smaller than the width WCL3 of the third column layer CL3. W14 <WCL3 is established. Thus, the contact region 14 is not in contact with the N-type second column layer CL2 but is in contact with only the P⁻-type third column layer CL3 among the drift layers 11 of the SJ structure. As illustrated in FIG. 8, the contact region 14 is also connected to the P-type first column layer CL1 through the P-type well region 12.

The contact region 14 and the source drawing regions 131 are in contact with the source electrode SE in the source contact region CA. The source contact region CA is provided at a position away from a column of the plurality of channel cells CS aligned in the Y-axis direction. For example, the source contact region CA is positioned between one group of the channel cells CS and the other group of the channel cells CS adjacent to each other in the X-axis direction. The source contact region CA is provided with a contact hole with the contact region 14 and the source drawing regions 131 as the bottom surface. Through the contact hole, the source electrode SE is in contact with the contact region 14 and the source drawing regions 131.

The source contact region CA has a width WCA in the X-axis direction of 1 μm or more and 5 μm or less, for example. An arrangement pitch PCA in the X-axis direction of the source contact regions CA is 2 μm or more and 10 μm or less, for example.

The plurality of trenches H is extended in the X-axis direction and arranged side by side at a fixed pitch in the Y-axis direction. The trenches H open to the front surface 10a side of the GaN layer 10. The trenches H are positioned between the plurality of channel cells CS. For example, the trench H is arranged between one channel cell CS and the other channel cell CS adjacent to each other in the Y-axis direction. More specifically, the trenches H are arranged to sandwich the channel cell CS from both sides in the Y-axis direction. The trench H has a width WH in the Y-axis direction of 0.1 μm or more and 1 μm or less, for example.

The gate insulating film 21 is provided on surfaces of the trenches H. The gate insulating film 21 is a silicon oxide film (SiO₂ film) or an aluminum oxide (Al₂O₃) film, for example. An insulating film 22 is provided on the bottom surfaces of the trenches H. The insulating film 22 is a SiO₂ film or an Al₂O₃ film, for example. The gate insulating film 21 and the insulating film 22 are in contact with each other in the trench H. For example, the insulating film 22 has a film thickness larger than that of the gate insulating film 21.

The gate electrode GE has an electrode part (hereinafter, trench gate) 31 arranged in the trench H through the gate insulating film 21 or the insulating film 22 and a wiring part 32 extended in the Y-axis direction over the plurality of channel cells CS. As with the trenches H, two or more of the trench gates 31 are also provided, and each of the two or more of the trench gates 31 is extended in the X-axis direction. The trench gates 31 and the wiring part 32 are connected to each other. The trench gates 31 are adjacent to the channel cells CS through the gate insulating film 21. The gate electrode GE is formed of impurity-doped polysilicon. The insulating film 41 is provided on the gate electrode GE. The insulating film 41 is a SiO₂ film or an Al₂O₃ film, for example.

As illustrated in FIG. 1, the two or more of the trench gates 31 have a second stripe pattern SP2 where the two or more of the trench gates 31 are aligned in the Y-axis direction. The first stripe pattern SP1 and the second stripe pattern SP2 intersect each other in plan view. When the repetition period of the first column layers CL1 or the second column layers CL2 in the X-axis direction of the first stripe pattern SP1 is set as a super junction period PSJ (one example of the “first period” of the present disclosure) and the repetition period of the trench gates 31 in the Y-axis direction of the second stripe pattern SP2 is set as a trench gate period P31 (one example of the “second period” of the present disclosure), the trench gate period P31 is shorter than the super junction period PSJ. P31<PSJ is established.

The source electrode SE is provided on the insulating film 41. The source electrode SE is in contact with the source drawing regions 131 and the contact region 14 through a contact hole provided in the insulating film 41. Thus, on-current of the vertical MOSFET flows to the source electrode SE through the source regions 13 and the source drawing regions 131. The potential of the well region 12 is fixed to the potential of the source electrode SE through the contact region 14.

The source electrode SE contains Al or Al-Si alloys. The source electrode SE may also have a barrier metal layer between the source electrode SE and the front surface 10a of the GaN layer 10. For example, a barrier metal layer arranged between the source electrode SE and the N⁺-type source drawing regions 131 may contain titanium (Ti). A barrier metal layer arranged between the source electrode SE and the P⁺-type contact region 14 may contain nickel (Ni) or a stacked-layer film of Ni/Gold (Au). Thus, the barrier metals of different materials may be used for the P⁺-type region and the N⁺-type region.

More specifically, the source electrode SE may be a stacked-layer of a Ti layer and an Al layer or a stacked-layer of a Ti layer and an Al—Si alloy layer on the N⁺-type region. The source electrode SE may also be a stacked-layer of a Ni layer and an Al layer or a stacked-layer of a Ni layer and an Al—Si alloy layer on the P⁺-type region. Alternatively, the source electrode SE may be a stacked-layer of Ni/Au and an Al layer or a stacked-layer of Ni/Au and an Al—Si alloy layer on the P⁺-type region. The source electrode SE may be an electrode that also serves as a source pad which is not illustrated or may be an electrode provided separately from a source pad.

### Effects of Embodiment 1

As described above, the insulated gate semiconductor device 1 according to the embodiment 1 of the present disclosure includes the GaN layer 10, the gate electrode GE provided on the first surface side of the GaN layer 10, the P-type contact region 14 provided in the GaN layer 10, and the drift layers 11 of the SJ structure provided in the GaN layer 10. The drift layers 11 contain the plurality of P-type first column layers CL1 extended in the Y-axis direction and the plurality of N-type second column layers CL2 extended in the Y-axis direction and have the first stripe pattern SP1 where the first column layers CL1 and the second column layer CL2 are alternately aligned in the X-axis direction intersecting the Y-axis direction. The gate electrode GE contains the plurality of trench gates 31 extended in the X-axis direction and has the second stripe pattern SP2 where the plurality of trench gates 31 is aligned in the Y-axis direction. The first stripe pattern SP1 and the second stripe pattern SP2 intersect each other in plan view. When the repetition period of the first column layers CL1 or the second column layers CL2 in the X-axis direction of the first stripe pattern SP1 is set as the super junction period PSJ and the repetition period of the trench gates 31 in the Y-axis direction of the second stripe pattern SP2 is set as a trench gate period P31, the trench gate period P31 is shorter than the super junction period PSJ. The contact region 14 has a P-type concentration higher than that of the first column layer CL1 and a width in the X-axis direction larger than that of the first column layer CL1.

Thus, the insulated gate semiconductor device 1 includes the drift layers 11 of the SJ structure, and therefore the impurity concentration of the drift layers 11 can be made higher and the on-resistance of the vertical MOSFET can be reduced while a reduction in breakdown voltage is suppressed. The extension direction of the first stripe pattern SP1 where the first column layers CL1 and the second column layers CL2 are alternately aligned and the extension direction of the second stripe pattern SP2 where the plurality of trench gates 31 is alternately aligned intersect each other. Thus, the pitch of the first stripe patterns SP1 (super junction period PSJ) and the pitch of the second stripe patterns SP2 (trench gate period P31) each can be independently set.

In the insulated gate semiconductor device 1, the trench gate period P31 is set to a narrower pitch than the super junction period PSJ (P31<PSJ). Thus, the channel width of the vertical MOSFET can be increased, and the on-resistance of the vertical MOSFET can be further reduced. In a vertical MOSFET where a drift layer contains a low-resistance material, such as GaN, the channel resistance accounts for a relatively large proportion of the resistance of an element. Therefore, the increasing the channel width is particularly effective in reducing the on-resistance.

The contact region 14 has a P-type concentration higher than that of the first column layer CL1 and a width in the X-axis direction larger than that of the first column layer CL1. Thus, the junction area between the contact region 14 and the source electrode SE can be enlarged, and therefore the resistance of the junction between the contact region 14 and the source electrode SE (i.e., source contact) can be reduced.

The drift layers 11 further have the third column layer CL3 provided in the GaN layer 10 and positioned under the contact region 14. The conductivity type of the third column layer CL3 is a P⁻-type having a concentration lower than that of the first column layer CL1. The third column layer CL3 is extended in the Y-axis direction and has a width in the X-axis direction larger than that of the first column layer CL1.

Thus, the junction capacitance to be formed in the contact region 14 can be suppressed to a low level as compared with a case where the second column layer CL2 is positioned under the contact region 14. When a drain voltage is applied, a depletion layer can be widely extended from the PN junction interface between the second column layer CL2 and the third column layer CL3 to the third column layer CL3 side, and therefore a reduction in breakdown voltage of the insulated gate semiconductor device 1 can be suppressed.

The contact region 14 is extended in the Y-axis direction and is provided in the vicinities of end parts in the X-axis direction of the trench gates 31. This eliminates the necessity of making source contact above the channel cells CS or between the channel cells CS adjacent to each other in the Y-axis direction, and therefore the arrangement pitch PCS (see FIG. 5) in the Y-axis direction of the channel cells CS can be narrowed. It is advantageous for narrowing the pitch of the trench gate period P31.

Further, there is no need to make source contact above the channel cells CS or between the channel cells CS adjacent to each other in the Y-axis direction, and therefore no gate-source short-circuit failures occur even when the arrangement pitch PCS in the Y-axis direction of the channel cells CS is narrowed. Thus, a reduction in yield due to a machining process can be suppressed even in the case of miniaturization. The SJ structure and a fine trench MOS structure can be simultaneously built.

### Modification of Embodiment 1

The above-described embodiment 1 describes that the third column layer CL3 is the P⁻-type. However, in the embodiment 1 of the present disclosure, the conductivity type of the third column layer CL3 is not limited to the P⁻-type. The conductivity type of the third column layer CL3 may be an N⁻-type having a concentration lower than that of the N-type second column layer CL2.

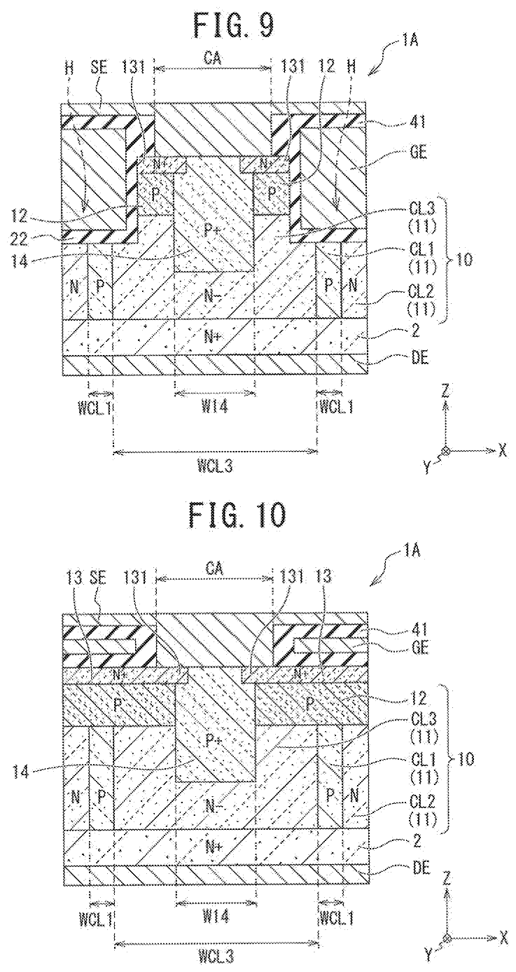

FIGS. 9 and 10 are cross-sectional views illustrating configuration examples of an insulated gate semiconductor device 1A (one example of the “semiconductor device” of the present disclosure) according to a modification of the embodiment 1 of the present disclosure. FIG. 9 corresponds to the cross-section obtained by cutting the plan view illustrated in FIG. 1 along the A1-A1′ line. FIG. 10 corresponds to the cross-section obtained by cutting the plan view illustrated in FIG. 1 along the B1-B1′ line.

As illustrated in FIGS. 9 and 10, the insulated gate semiconductor device 1A according to the modification of the embodiment 1 includes an N⁻-type third column layer CL3 having a concentration lower than that of the N-type second column layer CL2 in place of the P⁻-type third column layer CL3 illustrated in FIGS. 6 and 7.

Even such an aspect exhibits the same effects as those of the above-described embodiment 1. By replacing the P⁻-type third column layer CL3 with the N⁻-type third column layer CL3, at least one P⁻-type region having a concentration different from that of the other region disappears, and therefore there is a possibility that the number of manufacturing steps can be reduced and there is a possibility that the manufacturing cost can be reduced.

### Embodiment 2

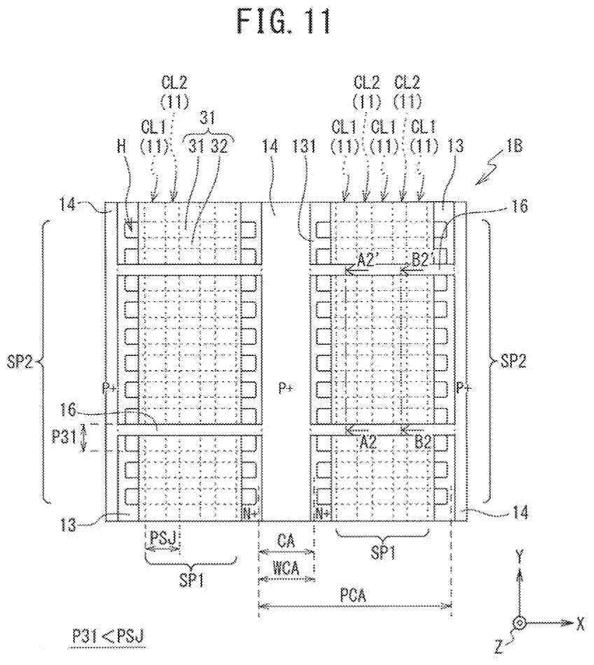

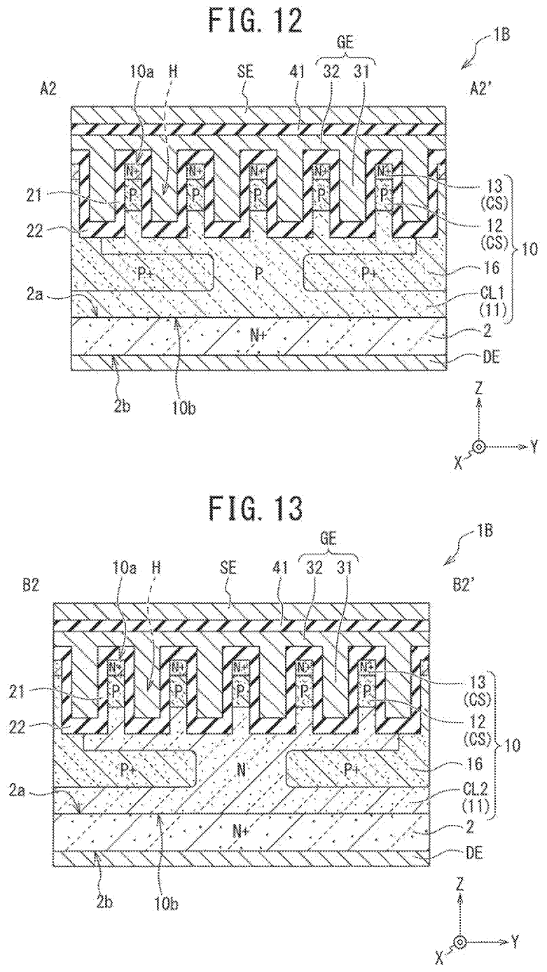

FIG. 11 is a plan view illustrating a configuration example of an insulated gate semiconductor device 1B (one example of the “semiconductor device” of the present disclosure) according to an embodiment 2 of the present disclosure. FIGS. 12 and 13 are cross-sectional views illustrating configuration examples of the insulated gate semiconductor device 1B according to the embodiment 2 of the present disclosure. FIG. 12 corresponds to the cross-section obtained by cutting the plan view illustrated in FIG. 11 along the A2-A2′ line. FIG. 13 corresponds to the cross-section obtained by cutting the plan view illustrated in FIG. 11 along the B2-B2′ line.

As illustrated in FIGS. 11 to 13, the insulated gate semiconductor device 1B according to the embodiment 2 further includes a P⁺-type high concentration layer 16 provided in the GaN layer 10 and having a P-type concentration higher than that of the P-type first column layer CL1.

As illustrated in FIG. 11, the P⁺-type high concentration layer 16 is connected to the P⁺-type contact regions 14. As illustrated in FIGS. 12 and 13, the P⁺-type high concentration layer 16 is connected to each of the P-type first column layer CL1 and the N-type second column layer CL2. The presence of the P⁺-type high concentration layer 16 reduces the resistance of the entire P-type layers in the drift layers 11.

The P⁺-type high concentration layer 16 is positioned between one of the trench gates 31 and the other one of the trench gates 31 adjacent to each other in the Y-axis direction. As illustrated in FIGS. 12 and 13, the P⁺-type high concentration layer 16 extends from a position between the trench gates 31 down to the trench gates 31 through the first column layer CL1 or the second column layer CL2. As illustrated in FIG. 13, the N-type second column layer CL2 functioning as a current path between the GaN substrate 2 and the well region 12 is narrowed (i.e., width of the current path) by the P⁺-type high concentration layer 16 extending down to the trench gates 31.

In the insulated gate semiconductor device 1B, the configurations other than the above are the same as those in the insulated gate semiconductor device 1 according to the embodiment 1. Thus, the insulated gate semiconductor device 1B according to this embodiment 2 exhibits the same effects as those of the above-described embodiment 1.

Further, the insulated gate semiconductor device 1B can improve the short circuit withstand time. When the channel of the vertical MOSFET is finely formed, current in a short circuit excessively increases and a short circuit current increases, causing a reduction in short circuit withstand time. However, the arrangement of the P⁺-type high concentration layer 16 (i.e., buried JFET structure) as illustrated in FIGS. 11 to 13 makes it possible to suppress the short circuit current to a low level and to secure the short circuit withstand time.

### Experiment and Results Thereof

The present disclosers performed an experiment to investigate the relation between the ratio of the trench pitch to the SJ pitch and the on-resistance RonA.

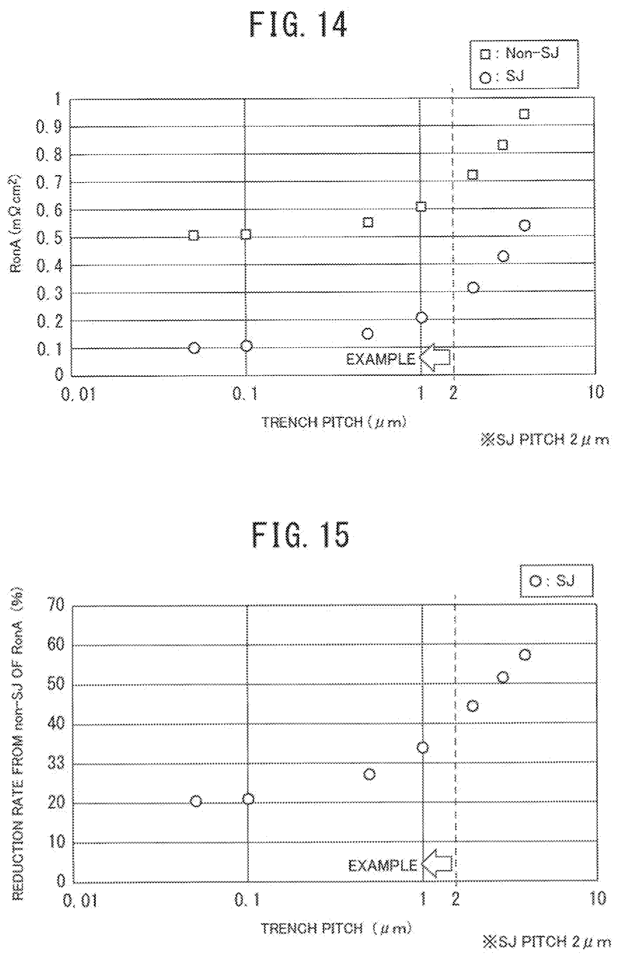

FIG. 14 is a graph showing the results of the experiment performed by the present disclosers and the relation between the trench gate period (hereinafter also referred to as the trench pitch) and the on-resistance RonA. In FIG. 14, the horizontal axis represents the trench pitch (μm) and the vertical axis represents the on-resistance RonA.

In the graph in FIG. 14, SJ indicates the insulated gate semiconductor device having the drift layers 11 of the SJ structure as illustrated in FIGS. 6 to 8. Non-SJ indicates an insulated gate semiconductor device having a drift region having no SJ structure and containing only an N-type region. A structural difference between the SJ and the Non-SJ is only the presence or absence of the SJ structure, and the other configurations are the same. SJ data and Non-SJ data illustrated in FIG. 14 are data for a drain-to-source voltage of 1400 V and a mobility of 75 cm²/Vs. The super junction period of the SJ (hereinafter also referred to as SJ pitch) was set to 2 μm.

For the SJ in FIG. 14, Trench pitch=SJ pitch is established when the trench pitch is 2 μm. Trench pitch<SJ pitch is established when the trench pitch is less than 2 μm. In the SJ in FIG. 14, the range where the trench pitch is less than 2 μm is one example of the present disclosure.

As can be understood by comparing the SJ and the Non-SJ in FIG. 14, it was confirmed that the presence of the drift layers of the SJ structure can reduce the on-resistance RonA. In the SJ in FIG. 14, it was confirmed that the on-resistance RonA tends to be lower as the trench pitch becomes smaller relative to the SJ pitch.

As illustrated in FIG. 14, in the Non-SJ, the on-resistance RonA was able to be reduced by only about half even when the trench pitch was miniaturized to 0.1 μm or less. In contrast thereto, in the SJ, the on-resistance RonA was able to be reduced to ⅕ or less by miniaturizing the trench pitch to 0.1 μm or less. It was confirmed that the SJ has a high on-resistance RonA reduction effect by miniaturizing the trench pitch as compared with the Non-SJ.

FIG. 15 is a graph created based on the graph in FIG. 14, and is a graph showing the relation between the trench pitch and a reduction rate of the RonA. In FIG. 15, the horizontal axis represents the trench pitch (μm). The vertical axis represents the reduction rate (%) from the non-SJ of the on-resistance RonA. As illustrated in FIG. 15, the trench pitch was 0.1 μm or less (i.e., the ratio of the trench pitch to the SJ pitch was 0.05 or less) and the reduction rate from the non-SJ of the on-resistance RonA was about 20%.

From the results, it was found that the ratio of the trench pitch to the SJ pitch (i.e., the ratio of the trench gate period P31 to the super junction period PSJ) is preferably 0.5 or less and more preferably 0.05 or less. Thus, the on-resistance RonA can be further reduced.

### Other Embodiments

As described above, although the present disclosure is described by the embodiments 1, 2, the discussion and the drawings forming part of this disclosure should not be understood as limiting the present disclosure. Various alternative embodiments and modifications will be apparent to those skilled in the art from this disclosure.

For example, the semiconductor layer of the present disclosure is not limited to the GaN layer but may also be a silicon carbide (SiC) layer. In a vertical MOSFET in which a drift layer contains a low-resistance material, such as SiC, the channel resistance is relatively large, and therefore the increasing the channel width is particularly effective in reducing the on-resistance. Further, the semiconductor layer of the present disclosure is not limited to the GaN layer or the SiC layer but may be a Si layer.

Thus, it is a matter of course that the present technology includes various embodiments and the like that are not described herein. At least one of various omissions, substitutions, and alternations of the constituent components can be performed without departing from the gist of the embodiments 1, 2 and the modifications described above. Further, the effects described in this specification are merely examples and are not limited, and other effects may also be involved.

The present disclosure can also take the following configurations.

(1)

A semiconductor device including:
a semiconductor layer;
a gate electrode provided on a first surface of the semiconductor layer;
a first conductivity-type contact region provided in the semiconductor layer; and
drift layers of a super junction structure provided in the semiconductor layer, in which
the drift layers contain
   a plurality of first conductivity-type first column layers extended in a first direction and a plurality of second conductivity-type second column layers extended in the first direction and have a first stripe pattern where the first column layers and the second column layers are alternately aligned in a second direction intersecting the first direction,
the gate electrode contains
a plurality of trench gates extended in the second direction and has a second stripe pattern where the plurality of trench gates is aligned in the first direction,
the first stripe pattern and the second stripe pattern intersect each other in plan view,
when the repetition period of the first column layers or the second column layers in the second direction of the first stripe pattern is set as a first period and the repetition period of the trench gates in the first direction of the second stripe pattern is set as a second period, the second period is shorter than the first period, and
the contact region has a concentration of the first conductivity type higher than that of the first column layer and a width in the second direction larger than that of the first column layer.
   (2)

The semiconductor device according to (1) above, in which
the drift layers further have
a third column layer provided in the semiconductor layer and positioned under the contact region,
the conductivity type of the third column layer is a first conductivity type having a concentration lower than that of the first column layer or a second conductivity type having a concentration lower than that of the second column layer, and
the third column layer is extended in the first direction and has a width in the second direction larger than that of the first column layer.
   (3)

A semiconductor device including:
a semiconductor layer;
a gate electrode provided on a first surface of the semiconductor layer;
a first conductivity-type contact region provided in the semiconductor layer; and
drift layers of a super junction structure provided in the semiconductor layer, in which
the drift layers contain
a plurality of first conductivity-type first column layers extended in a first direction and a plurality of second conductivity-type second column layers extended in the first direction and have a first stripe pattern where the first column layers and the second column layers are alternately aligned in a second direction intersecting the first direction,
the gate electrode contains a plurality of trench gates extended in the second direction and has a second stripe pattern where the plurality of trench gates is aligned in the first direction,
   the first stripe pattern and the second stripe pattern intersect each other in plan view,
when the repetition period of the first column layers or the second column layers in the second direction of the first stripe pattern is set as a first period and the repetition period of the trench gates in the first direction of the second stripe pattern is set as a second period, the second period is shorter than the first period,
the contact region has a concentration of the first conductivity type higher than that of the first column layer,
the drift layers further have
a third column layer provided in the semiconductor layer and positioned under the contact region,
the conductivity type of the third column layer is a first conductivity type having a concentration lower than that of the first column layer or a second conductivity type having a concentration lower than that of the second column layer, and
the third column layer is extended in the first direction and has a width in the second direction larger than that of the first column layer.
   (4)

The semiconductor device according to any one of (1) to (3) above, in which
the contact region is extended in the first direction and is positioned in the vicinities of end parts in the second direction of the trench gates.
   (5)

The semiconductor device according to any one of (1) to (4) above, further including:
a first conductivity-type high concentration layer provided in the semiconductor layer and having a concentration of the first conductivity type higher than that of the first column layer, in which
the high concentration layer is positioned between one of the trench gates and the other one of the trench gates adjacent to each other in the first direction and extends from a position between the one of the trench gates and the other one of the trench gates down to the trench gates through the first column layer.
   (6)

The semiconductor device according to (5) above, in which the high concentration layer is connected to the contact region.

(7)

The semiconductor device according to (5) or (6) above, in which the high concentration layer is connected to the first column layer.

(8)

The semiconductor device according to any one of (1) to (7) above, further including:
channel cells provided in the semiconductor layer and positioned between the one of the trench gates and the other one of the trench gates adjacent to each other in the first direction, in which
the channel cells have a first conductivity-type well region and a second conductivity-type source region in contact with the well region.
   (9)

The semiconductor device according to (8) above, further including:
a second conductivity-type source drawing region provided in the semiconductor layer and drawing the source region to the outside of the channel cells, in which
the source drawing region is in contact with the contact region.
   (10)

The semiconductor device according to (9) above, further including:
a source electrode provided on a first principal surface of the semiconductor layer, in which
the source electrode is in contact with the source drawing region and the contact region.
   (11)

The semiconductor device according to any one of (1) to (10) above, in which the ratio of the second period to the first period is 0.5 or less.

(12)

The semiconductor device according to any one of (1) to (10) above, in which the ratio of the second period to the first period is 0.05 or less.

(13)

The semiconductor device according to any one of (1) to (12) above, in which the semiconductor layer is a SiC layer or a GaN layer.

1. A semiconductor device comprising:
a semiconductor layer;
a gate electrode provided on a first surface of the semiconductor layer;
a first conductivity-type contact region provided in the semiconductor layer; and
drift layers of a super junction structure provided in the semiconductor layer, wherein
the drift layers contain a plurality of first conductivity-type first column layers extended in a first direction and a plurality of second conductivity-type second column layers extended in the first direction and have a first stripe pattern where the first column layers and the second column layers are alternately aligned in a second direction intersecting the first direction,
the gate electrode contains a plurality of trench gates extended in the second direction and has a second stripe pattern where the plurality of trench gates is aligned in the first direction,
the first stripe pattern and the second stripe pattern intersect each other in plan view,
when a repetition period of the first column layers or the second column layers in the second direction of the first stripe pattern is set as a first period and a repetition period of the trench gates in the first direction of the second stripe pattern is set as a second period, the second period is shorter than the first period, and
the contact region has a concentration of the first conductivity type higher than the concentration of the first conductivity type of the first column layer and a width in the second direction larger than the width in the second direction of the first column layer.

2. The semiconductor device according to claim 1, wherein
the drift layers further have
a third column layer provided in the semiconductor layer and positioned under the contact region,
a conductivity type of the third column layer is a first conductivity type having a concentration lower than the concentration of the first column layer or a second conductivity type having a concentration lower than the concentration of the second column layer, and
the third column layer is extended in the first direction and has a width in the second direction larger than the width in the second direction of the first column layer.

3. A semiconductor device comprising:
a semiconductor layer;
a gate electrode provided on a first surface of the semiconductor layer;
a first conductivity-type contact region provided in the semiconductor layer; and
drift layers of a super junction structure provided in the semiconductor layer, wherein
the drift layers contain a plurality of first conductivity-type first column layers extended in a first direction and a plurality of second conductivity-type second column layers extended in the first direction and have a first stripe pattern where the first column layers and the second column layers are alternately aligned in a second direction intersecting the first direction,
the gate electrode contains a plurality of trench gates extended in the second direction and has a second stripe pattern where the plurality of trench gates is aligned in the first direction,
the first stripe pattern and the second stripe pattern intersect each other in plan view,
when a repetition period of the first column layers or the second column layers in the second direction of the first stripe pattern is set as a first period and a repetition period of the trench gates in the first direction of the second stripe pattern is set as a second period, the second period is shorter than the first period,
the contact region has a concentration of the first conductivity type higher than the concentration of the first conductivity type of the first column layer,
the drift layers further have
a third column layer provided in the semiconductor layer and positioned under the contact region,
a conductivity type of the third column layer is a first conductivity type having a concentration lower than the concentration of the first column layer or a second conductivity type having a concentration lower than the concentration of the second column layer, and
the third column layer is extended in the first direction and has a width in the second direction larger than the width in the second direction of the first column layer.

4. The semiconductor device according to claim 1, wherein
the contact region is extended in the first direction and is positioned in vicinities of end parts in the second direction of the trench gates.

5. The semiconductor device according to claim 1, further comprising:
a first conductivity-type high concentration layer provided in the semiconductor layer and having a concentration of the first conductivity type higher than the concentration of the first conductivity type of the first column layer, wherein
the high concentration layer is positioned between one of the trench gates and another one of the trench gates adjacent to each other in the first direction and extends from a position between the one of the trench gates and the another one of the trench gates down to the trench gates through the first column layer.

6. The semiconductor device according to claim 5, wherein the high concentration layer is connected to the contact region.

7. The semiconductor device according to claim 5, wherein the high concentration layer is connected to the first column layer.

8. The semiconductor device according to claim 1, further comprising:
channel cells provided in the semiconductor layer and positioned between one of the trench gates and another one of the trench gates adjacent to each other in the first direction, wherein
the channel cells have a first conductivity-type well region and a second conductivity-type source region in contact with the well region.

9. The semiconductor device according to claim 8, further comprising:
a second conductivity-type source drawing region provided in the semiconductor layer and drawing the source region to an outside of the channel cells, wherein
the source drawing region is in contact with the contact region.

10. The semiconductor device according to claim 9, further comprising:
a source electrode provided on a first principal surface of the semiconductor layer, wherein the source electrode is in contact with the source drawing region and the contact region.

11. The semiconductor device according to claim 1, wherein a ratio of the second period to the first period is 0.5 or less.

12. The semiconductor device according to claim 1, wherein a ratio of the second period to the first period is 0.05 or less.

13. The semiconductor device according to claim 1, wherein the semiconductor layer is a SiC layer or a GaN layer.
